(19) United States
(12) Patent Application Publication
(10) Pub. No.: US 2008/0220605 A1
(43) Pub. Date: Sep. 11, 2008

(54) METHOD OF MANUFACTURING FLASH MEMORY DEVICE

(76) Inventors: Jung Gu Lee, Seongnam-si (KR); Whee Won Cho, Cheongju-Si (KR); Seong Hwan Myung, Suwon-Si (KR); Suk Joong Kim, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/955,836

(22) Filed: Dec. 13, 2007

(30) Foreign Application Priority Data
Mar. 5, 2007 (KR) 2007-21281

(51) Int. Cl. H01L 21/283

(52) U.S. Cl. 438/593; 257/E21.159

(57) ABSTRACT

The present invention discloses a method of manufacturing a flash memory device comprising the steps of forming a first insulating layer and a first conductive layer on a semiconductor substrate; etching the first conductive layer, the first insulating layer and the semiconductor substrate to form a trench; forming an isolation layer on a region on which the trench is formed; forming a second conductive layer to make the second conductive layer contact with the first conductive layer; and removing the second conductive layer formed on the isolation layer.

### CROSS-REFERENCE TO RELATED APPLICATIONS

The priority of Korean Patent Application No. 2007-21281, filed on Mar. 5, 2007, is hereby claimed and the disclosure of which is incorporated herein by reference in its entirety.

### BACKGROUND OF THE INVENTION

The present invention relates to a method of manufacturing a flash memory device, more particularly relates to a method of manufacturing a flash memory device for preventing void from being generated when a large-surfaced floating gate is formed.

In the semiconductor memory devices, a flash memory device comprises a plurality of memory cells for storing data. A floating gate is formed in each memory cell and data is stored in the floating gate. As the integration of the device is increased, the width of the floating gate becomes narrow. Accordingly, to secure an area and a volume of the floating gate, the floating gate is formed thickly. However, the aspect ratio is increased due to an increase of the thickness. For the above described reason, a void may be generated in an isolation layer when the isolation layer is formed, and so stability of the device can be lowered.

### SUMMARY OF THE INVENTION

In a method of the present invention, a conductive layer for a floating gate consists of a first conductive layer and a second conductive layer. However, the first conductive layer has a small thickness to lower the aspect ratio, and an isolation layer is formed such that a void is not generated in the isolation layer. After the isolation layer is formed, the second conductive layer is formed thickly to secure an area of the floating gate which is subsequently formed.

The method of manufacturing a flash memory device according to the present invention comprises the steps of forming a first insulating layer and a first conductive layer on a semiconductor substrate; etching the first conductive layer, the first insulating layer and the semiconductor substrate to form a trench; forming an isolation layer on a region on which the trench is formed; forming a second conductive layer in contact with the first conductive layer; and removing the second conductive layer formed on the isolation layer.

The method of manufacturing a flash memory device of the present invention can further comprise the steps of forming a dielectric layer on the patterned second conductive layer and the isolation layer; and forming a third conductive layer on the dielectric layer. In an embodiment, the first conductive layer can have a thickness of 50 Å to 100 Å.

The step of forming the trench can comprise the steps of forming the first insulating layer and the first conductive layer on the semiconductor substrate; forming patterns of a mask layer on the first conductive layer; patterning the first conductive layer and the first insulating layer in accordance with the patterns of the mask layer; and removing a portion of the semiconductor substrate according to the patterns of the mask layer.

The pattern of the mask layer can have a stacked structure of an etching stop layer and an oxide layer, and the etching stop layer can be formed of a nitride layer.

The step of patterning the second conductive layer cancomprise the steps of forming patterns of a photoresist layer on the second conductive layer; and etching the second conductive layer in accordance with the patterns of the photoresist layer.

The step of forming the patterns of the photoresist layer can comprise the steps of forming the photoresist layer on the second conductive layer; and performing an exposure process and a developing process for a portion of the photoresist layer.

The photoresist layer can have an opening included in the isolation area, and the step of patterning the second conductive layer can be performed for exposing the isolation layer. Also, the pattern of the photoresist layer is preferably removed after patterning the second conducive layer.

### BRIEF DESCRIPTION OF THE DRAWINGS

The above and other features and advantages of the present invention will become readily apparent by reference to the following detailed description when considered in conjunction with the accompanying drawings wherein:

FIG. 1A to FIG. 1H are sectional view of a flash memory device for illustrating a method of manufacturing a flash memory device according to the present invention.

### DESCRIPTION OF SPECIFIC EMBODIMENTS

Hereinafter, the preferred embodiments of the present invention will be explained in more detail with reference to the accompanying drawings. However, the embodiments of the present invention may be modified variously and a scope of the present invention should not be limited to the embodiment described below. The description herein is provided for illustrating the present invention more completely to those skilled in the art.

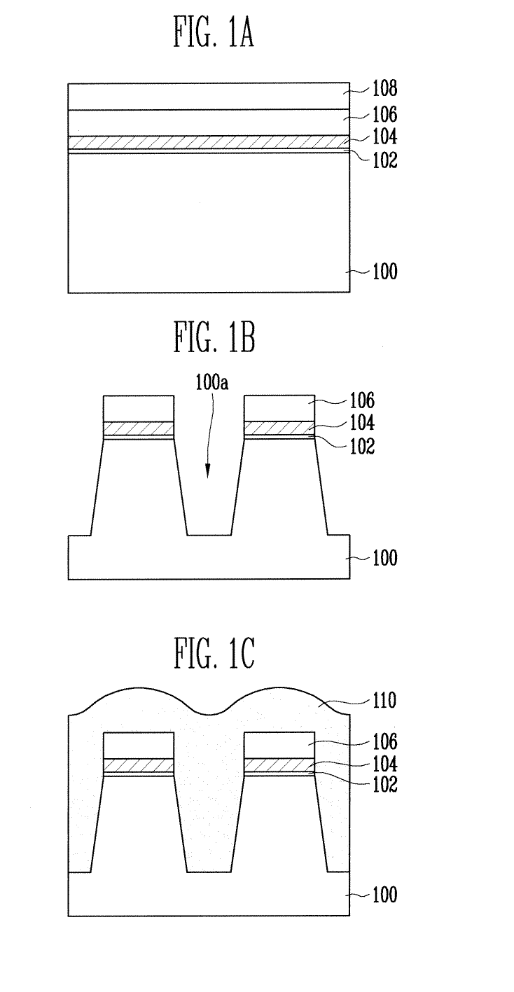

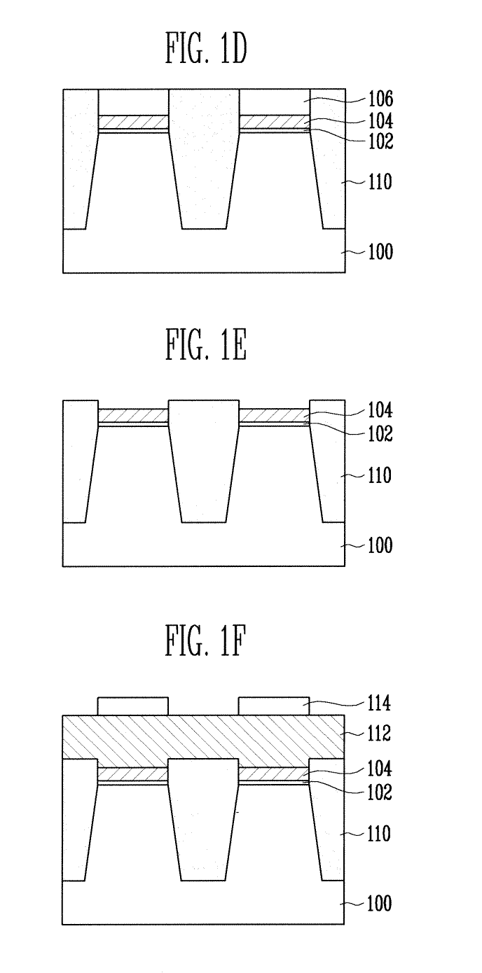

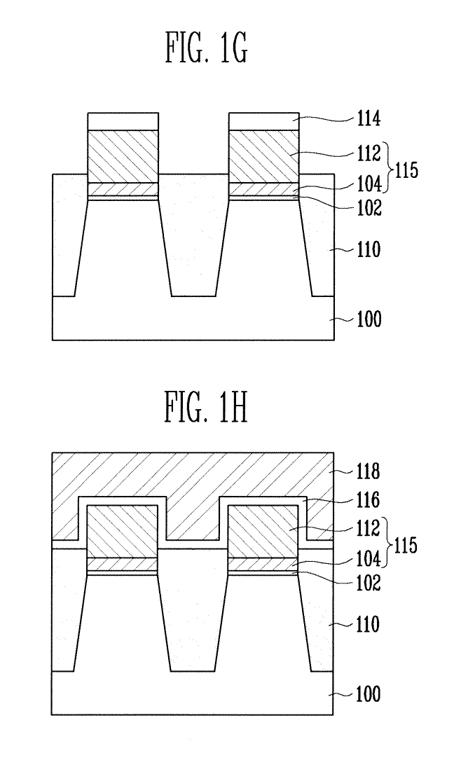

FIG. 1A to FIG. 1H are sectional view of a flash memory device for illustrating a method of manufacturing a flash memory device according to the present invention.

Referring to FIG. 1A, a first insulating layer 102 for a tunnel insulating layer, a first conductive layer 104 for a floating gate, an etching stop layer 106 and a first mask layer 108 are formed on a semiconductor substrate 100. The first insulating layer 102 may be formed of an oxide layer and the first conductive layer 104 may be formed of a polysilicon layer. In this embodiment, the first conductive layer 104 may have a thickness of 50 Å to 100 Å. The etching stop layer 106 may be formed of a nitride layer and it is preferable to form the first mask layer 108 from oxide-based material.

Referring to FIG. 1B, the first mask layer (108 in FIG. 1A) is patterned and an etching process is performed using the patterned first mask layer. The etching stop layer 106, the first conductive layer 104 and the first insulating layer 102 are patterned through an etching process, and a portion of the semiconductor substrate 100 is removed to form a trench 100a. During the etching process, the first mask layer (108 in FIG. 1A) can be removed entirely. If the first mask layer remains after the etching process, the remaining first mask layer is then removed. At this time, a part of the etching stop layer 106 can be removed.

Referring to FIG. 1C, a second insulating layer 110 is formed to fill completely the trench (100a in FIG. 1B). The second insulating layer 110 may be formed of an oxide layer. With respect to the integration, the first conductive layer 104 is not thick (e.g., 50 Å to 100 Å), and so an aspect ratio of the trench (100a in FIG. 1B) is low. Due to the low aspect ratio, the second insulating layer 110 can be uniformly formed without generating void in the trench (100a in FIG. 1B).

Referring to FIG. 1D, a chemical mechanical polishing (CMP) process is carried out for exposing the etching stop layer 106. From this, the second insulating layer 110 remains on only a region on which the trench (100a in FIG. 1B) is formed, and this remaining second insulating layer 110 acts as an isolation layer (hereinafter, referred to as “isolation layer”).

Referring to FIG. 1E, the etching stop layer (106 in FIG. 1D) is removed. Accordingly, the first conductive layer 104 is exposed, and the isolation layer 110 protrudes more than the first conductive layer 104.

Referring to FIG. 1F, a second conductive layer 112 for a floating gate is formed on the isolation layer 110 including the first conductive layer 104. Since the second conductive layer 112 is used as the floating gate together with the first conductive layer 104, it is preferable that the second conductive layer is formed of a polysilicon layer.

In this embodiment, the chemical mechanical polishing (CMP) process is carried out for exposing the isolation layer 110 so that the floating gate consisting of the first conductive layer 104 and the second conductive layer 112 may be formed. Since the first conductive layer 104 for the floating gate is thin, however, an effect of increase of an area of the floating gate is diminished.

To solve the above-described problem, in the present invention, the second conductive layer 112 for the floating gate is formed such that the isolation layer 110 is completely covered with the second conductive layer, and the second conductive layer 112 is then patterned to form the floating gate. The above process will be described in more detail.

A second mask layer 114 is formed on the second conductive layer 112. The second mask layer 114 may be formed of a photoresist layer; and an exposure process and developing process according to a width of an active area are performed to form patterns of the second mask layer 114.

Referring to FIG. 1G, an etching process in which the patterns of the second mask layer 114 are utilized is performed to remove a portion of the second conductive layer 112. The removed region of the second conductive layer 112 is the isolation area on which the isolation layer 110 is formed. A portion of the second conductive layer 112 is removed by patterning the second conductive layer 112 to expose the isolation layer 110. The first conductive layer 104 and the second conductive layer 112 become floating gates 115 through the above-described process. When the etching process is performed, the second mask layer 114 can be removed completely or a portion of the second mask layer may remain. If a portion of the second mask layer 114 remains, the residue of the second mask layer should be removed.

Referring to FIG. 1H, a dielectric layer 116 is formed along the floating gate 115 and a surface of the isolation layer 110 and a third conductive layer 118 for a control gate is formed on the dielectric layer 116.

In a process of manufacturing a flash memory device according to the present invention, the floating gate consists of the first conductive layer and the second conductive layer. However, the second conductive layer is formed after forming the isolation layer and the second conductive layer is patterned according to the patterns of the photoresist layer. Accordingly, the area of the floating gate is increased and it is possible to prevent a void from being generated when the conductive layer for the floating gate is formed.

Although the invention has been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a flash memory device, comprising the steps of;
forming a first insulating layer and a first conductive layer on a semiconductor substrate;
etching the first conductive layer, the first insulating layer and the semiconductor substrate to form a trench;
forming an isolation layer on a region on which the trench is formed;
forming a second conductive layer in contact with the first conductive layer; and
patterning the second conductive layer to remove the second conductive layer formed on the isolation layer.

2. The method of manufacturing a flash memory device of claim 1, further comprising the steps of;
forming a dielectric layer on the patterned second conductive layer and the isolation layer; and
forming a third conductive layer on the dielectric layer.

3. The method of manufacturing a flash memory device of claim 1, comprising forming the first conductive layer with a thickness in a range of 50 Å to 100 Å.

4. The method of manufacturing a flash memory device of claim 1, wherein the step of forming the trench comprises the steps of;
forming a pattern of a mask layer on the first conductive layer;
patterning the first conductive layer and the first insulating layer in accordance with the pattern of the mask layer; and
removing a portion of the semiconductor substrate according to the pattern of the mask layer.

5. The method of manufacturing a flash memory device of claim 4, wherein the pattern of the mask layer has a stacked structure of an etching stop layer and an oxide layer.

6. The method of manufacturing a flash memory device of claim 5, wherein the etching stop layer is formed of a nitride layer.

7. The method of manufacturing a flash memory device of claim 1, wherein the step of patterning the second conductive layer comprises the steps of;
forming patterns of a photoresist layer on the second conductive layer; and
etching the second conductive layer in accordance with the patterns of the photoresist layer.
